(19) United States
(12) Patent Application Publication
(10) Pub. No.: US 2009/0189175 A1
(43) Pub. Date: Jul. 30, 2009

(54) Side view type light emitting diode package

(75) Inventors: Ik-Seong Park, Seoul (KR); Sun-Hong Kim, Incheon (KR); Jin-Won Lee, Yongin-si (KR); Kyoung-Il Park, Busan (KR)

Correspondence Address: THE NATH LAW GROUP, 112 South West Street, Alexandria, VA, 22314, US

(73) Assignee: ALTI-ELECTRONICS CO., LTD., Gyeonggi-do (KR)

(21) Appl. No.: 12/078,117

(22) Filed: Mar. 27, 2008

(30) Foreign Application Priority Data
Jan. 25, 2008 (KR) 10-2008-0008223

(51) Int. Cl. H01L 33/00

(52) U.S. Cl. 257/99; 257/E33.001

(57) ABSTRACT

Disclosed is a side view light emitting diode (LED) package whose light emitting surface has been relatively expanded. The LED package includes a housing and a lead frame extended externally through the housing and bent in a direction of the recessed space. The housing includes a reflecting housing having a cavity and a supporting housing.

### CROSS-REFERENCE TO RELATED APPLICATION

This application claims priority from and the benefit of Korean Patent Application No. 10-2008-0008223, filed on Jan. 25, 2008, which is hereby incorporated by reference for all purposes as if fully set forth herein.

### BACKGROUND OF THE INVENTION

1. Field of the Invention

This invention is directed to a field of a light emitting diode (LED) package, and particularly, to a side view type LED package.

2. Description of the Related Art

In recent years, industries associated with light emitting diodes (LEDs) have sharply grown up with the advancement of information technologies. LEDs are widely employed as a backlight to represent numerals or characters in various electronic gadgets.

These LEDs are commonly used in the form of a package together with some other components.

An LED package includes an LED chip to emit light, a housing to accommodate the LED chip, electrodes to connect the LED package with a device on which the LED package will be mounted.

LED packages can be classified into top view types and side view types. In the former type, LED packages directly illuminate a screen, and, on the contrary, in the latter type, light generated from LEDs is firstly directed to a light guiding plate, and then reflected by the light guiding plate to illuminate a screen.

Side view type LED packages may greatly reduce the size of a device to which the LED package will be applicable as compared to top view type LED packages. Accordingly, side view type LED packages are more commonly used as a backlight for mobile phones, navigators, laptop computers, and the like.

FIG. 1 is a front view illustrating a side view type LED package 10 according to the prior art.

Referring to FIG. 1, LED package 10 includes a reflecting housing 11, a supporting housing 13, and a lead frame 14.

Reflecting housing 11 has a cavity 12 at its center, and a supporting portion 11a at its lower and middle portion. Supporting portion 11a is extended downwardly from the lower and middle portion. Supporting portion 11a is thicker than an upper portion of reflecting housing 11.

Supporting housing 13 is attached to a rear side of reflecting housing 11. Lead frame 14 on which an LED chip (not shown) is seated is exposed through cavity 12 and placed on supporting housing 13.

Lead frame 14 is protruded in the bottom direction of LED package 10 from between reflecting housing 11 and supporting housing 13, bent in the rear direction of LED package 11, and re-bent in the left or right direction of LED package 11. Finally, the end of lead frame 14 that has been bent in the left or right direction is bent in the front direction of LED package 11 to come in tight contact with a bottom surface of supporting housing 13.

Supporting portion 11a of reflecting housing 11 has the same thickness as that of a part of lead frame 14 which has been protruded in the bottom surface, and therefore, may support LED package 10 against a device (not shown) on which LED package 10 will be mounted.

In the above-structured LED package 10, however, the outward protruding lead frame 14 may cause the light emitting surface of the LED chip (not shown) to be small relative to the entire area of LED package 10 since the entire area is restrictive and some of the entire area should be assigned for the protruding portion of lead frame 14.

Also, additional necessity of supporting portion 11a may act as a limitation to the area and shape of the light emitting surface.

### SUMMARY OF THE INVENTION

Accordingly, the present invention has been designed to solve the aforementioned problems and an aspect of the present invention provides a side view type LED package having a space formed by making the supporting housing recessed, so that the end of the lead frame can be bent in the space and covered by the reflecting housing as seen from the front side of the LED package.

Additional features of the invention will be set forth in the description which follows, and in part will be apparent from the description, or may be learned by practice of the invention.

An exemplary embodiment of the present invention provides a side view light emitting diode package including: a housing including a reflecting housing having a cavity and a supporting housing attached to a rear portion of the reflecting housing, the supporting housing having a recessed space; and a lead frame interposed between the reflecting housing and the supporting housing and extended externally through the housing and bent along the recessed space.

One of the reflecting housing and the supporting housing may have a groove in its bottom portion, through which the lead frame is extended externally.

The lead frame may be extended under a bottom surface of the supporting housing and bent along the recessed space.

The lead frame may be extended and bent to be shaped as a reversed “T” as seen from a rear side of the light emitting diode package.

One of the reflecting housing and the supporting housing may have a groove in its side portion, through which the lead frame is extended.

The lead frame may be extended under a side portion of the supporting housing and is bent along the recessed space.

The lead frame may be further protruded beyond an outline of the reflecting housing.

The lead frame may be covered by the reflecting housing as seen from a front side of the light emitting diode package.

The reflecting housing may have an upper portion and a lower portion, and the upper portion has the same thickness as that of the lower portion.

The upper portion may be symmetrical to the lower portion with respect to a middle line between the upper portion and the lower portion.

The reflecting housing may have a barrier wall protruded from a front surface of the reflecting housing to surround the cavity.

It is to be understood that both the foregoing general description and the following detailed description are exemplary and explanatory and are intended to provide further explanation of the invention as claimed.

### BRIEF DESCRIPTION OF THE DRAWINGS

The above and other features of the present invention will be described in reference to certain exemplary embodiments thereof with reference to the attached drawings in which:

FIG. 1 is a front view illustrating a side view type LED package according to the prior art;

FIGS. 2 and 3 are perspective views illustrating a side view type LED package according to an exemplary embodiment of the present invention;

FIG. 4 is a rear view of the side view type LED shown in FIG. 2;

FIG. 5 is a rear view of a variation of the side view type LED package shown in FIG. 2;

FIG. 6 is a bottom view of another variation of the side view type LED package shown in FIG. 2; and

FIGS. 7 and 8 are perspective views illustrating a side view type LED package according to another exemplary embodiment of the present invention.

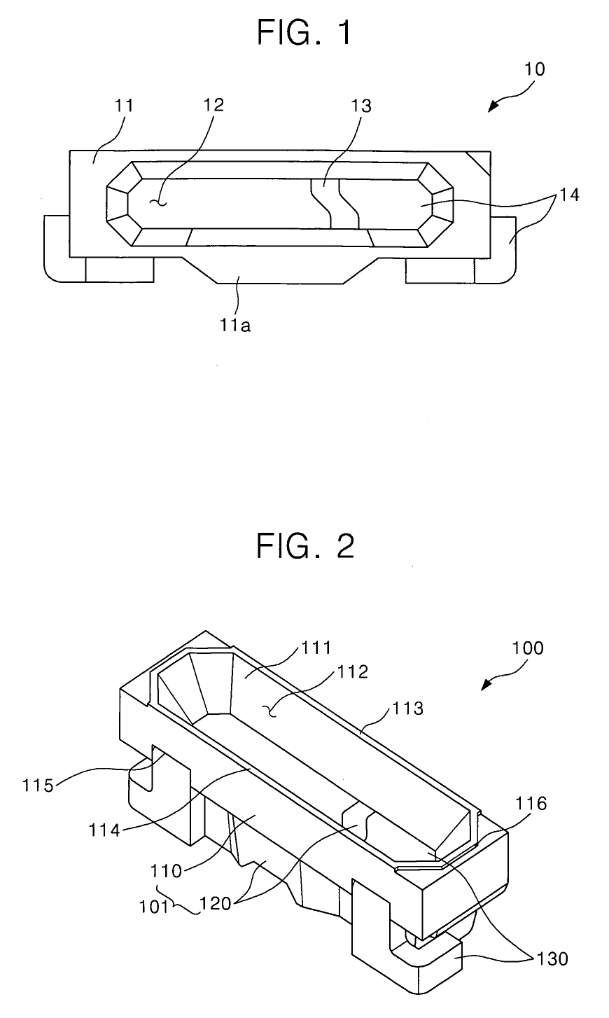

### DETAILED DESCRIPTION OF THE INVENTION

Reference will now be made in detail to embodiments of the present invention, examples of which are illustrated in the accompanying drawings, wherein like reference numerals refer to the like elements throughout. The embodiments are described below in order to explain the present invention by referring to the figures.

Throughout the specification, the term “front side” refers to a part of an LED package where a light emitting surface will be formed, the term “rear side” an opposite side of the front side, and the term “bottom side” a portion of the LED package which is seated on a device to which the LED package will be applied, the term “top side” an opposite side of the bottom side, the term “left side” a left portion of the LED package and “right side” a right portion thereof as seen from the front side.

And, the term “front direction” or “direction of front side”, “rear direction” or “direction of rear side”, “left direction” or “direction of left side”, “right direction” or “direction of right side”, “top direction” or “direction of top side”, and “bottom direction” or “direction of bottom side”, respectively, refer to a direction which the front side, the rear side, the left side, the right side, the top side, and the bottom side look toward, respectively.

Hereinafter, exemplary embodiments of the present invention will be described in more detail with reference to accompanying drawings.

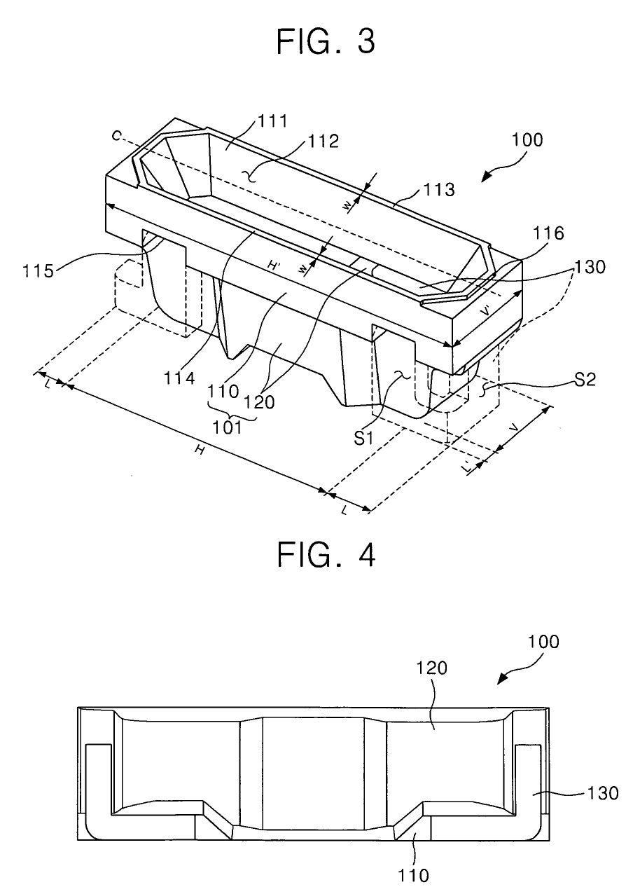

FIGS. 2 and 3 are perspective views illustrating a side view type LED package 100 according to an exemplary embodiment of the present invention. FIG. 4 is a rear view of side view type LED package 100 shown in FIG. 2.

Referring to FIGS. 2 to 4, LED package 100 includes a housing 101 and a lead frame 130. Housing 101 includes a reflecting housing 110 and a supporting housing 120. Lead frame 130 on which an LED chip (not shown) will be mounted is interposed between reflecting housing 110 and supporting housing 120.

A cavity 112 is prepared in reflecting housing 110 by having an inner wall 111 formed in the inside of reflecting housing 110. Inner wall 111 is inclined at a prescribed angle with respect to a front and rear axis, so that cavity 112 may be narrow in width as going in the rear direction.

Inner wall 111 thus structured may effectively reflect the light generated from the LED chip (not shown), so that light efficiency may be improved.

Reflecting housing 110 has an upper portion 113 and lower portion 114. A width W of upper portion 113 may be equal to that of lower portion 114 over the entire front surface of reflecting housing 110. Upper portion 113 and lower portion 114 may be symmetrical to each other with respect to a horizontal axis C.

Such a symmetrical structure may enlarge cavity 112 at least as much as a space which has been occupied by supporting portion 11a, and as a result the light emitting surface of LED package 100 may be expanded.

Reflecting housing 110 may have a barrier wall 116 protruded from its front surface.

Barrier wall 116 is extended from inner wall 111 and prevents the overflow of a sealer (not shown) to be filled in cavity 112 to protect the LED chip (not shown).

Supporting housing 120 may be recessed such that a first width H and a first height V of supporting housing 120 are smaller than a second width H′ and a second height V′ of reflecting housing 110, respectively.

This leaves spaces S1 and S2 in supporting housing 120. Space S1 is provided by recessing supporting housing 120 in the front direction, and space S2 in the left or right direction.

A part of lead frame 130 on which the LED chip (not shown) is mounted is placed on supporting housing 120 and exposed externally through cavity 112, and an end of the lead frame 130 is extended externally through a groove 115 that has been prepared in a bottom side of reflecting housing 110 or supporting housing 120.

The extended part of lead frame 130 is bent along space S1 and then along space S2, thereby ending up being located in spaces S1 and S2.

A part of lead frame 130, located in space S1, is perpendicularly bent with respect to horizontal axis C.

Accordingly, second width H′ of reflecting housing 110 is equal to the sum of first width H of supporting housing 120 and twice a third width L of a part of lead frame 130 extended in the left or right direction, and second height V′ of reflecting housing 110 is equal to the sum of first height V of supporting housing 120 and a third height L′ of a part of lead frame 130 extended in the front direction.

In short, lead frame 130 may be completely covered by reflecting housing 110 as seen from the front side of LED package 100.

Therefore, reflecting housing 110 may be expanded as much as a space which has been occupied by the extended portion of lead frame 130, which in turn may increase the superficial area of cavity 112.

A consequence is the increase in the amount of light and radiating range of beams generated from LED chip (not shown).

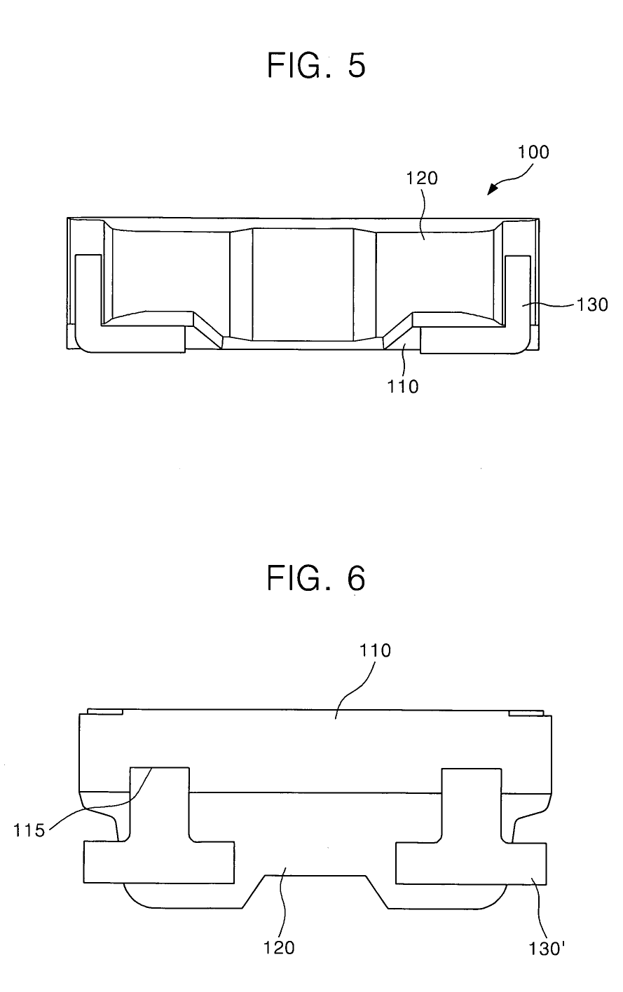

FIG. 5 is a rear view of a variation of the side view type LED package 100 shown in FIG. 2. As shown in FIG. 5, lead frame 130 may be further protruded e.g. about 100 μm below a bottom surface of reflecting housing 110 to make a balance in thickness or height with a device, for example a light guiding plate, on which LED package 100 will be mounted.

FIG. 6 is a bottom view of another variation of the side view type LED package 100 shown in FIG. 2.

Referring to FIG. 6, a lead frame 130′ is extended in the rear direction through groove 115 that has been bored in reflecting housing 110 and then in the left and right direction. Accordingly, lead frame 130′ is shaped as a reversed “T” as seen from the rear side of LED package 100.

Lead frame 130′ may function as an electrode connecting between LED package 100 and a device on which LED package 100 will be mounted. The reversed “T” shaped structure may increase the superficial area of lead frame 130′, and accordingly, lead frame 130′ may be more easily connected to the device as mounted and the occurrence of a short circuit may be effectively prevented.

In addition, lead frame 130′ may dissipate heat generated from LED package 100, and therefore, increased superficial area may also enable more efficient heat dissipation.

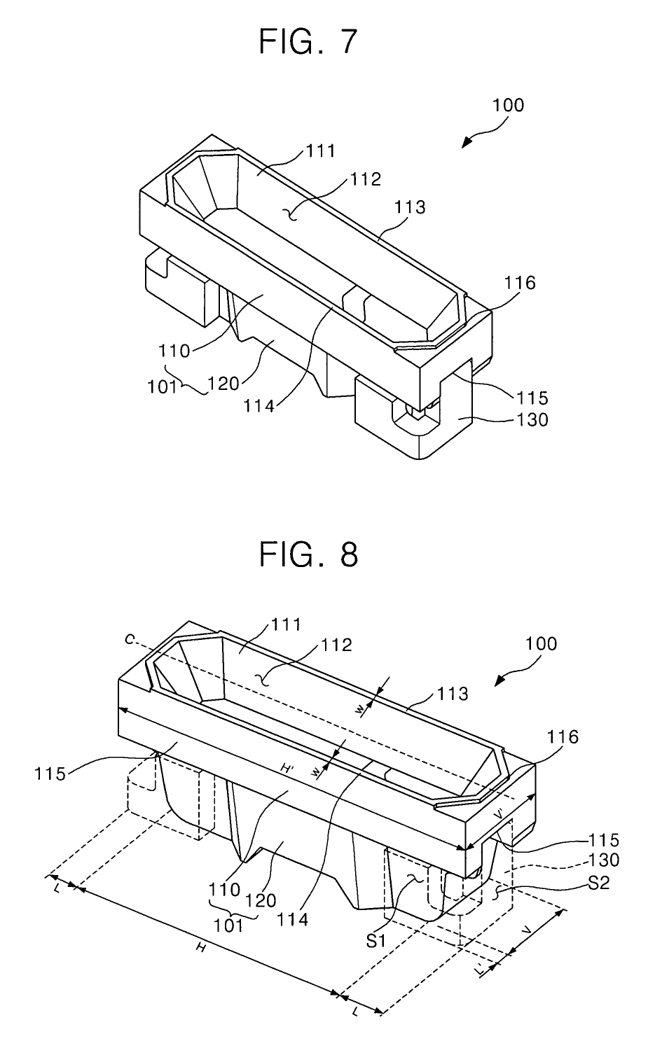

FIGS. 7 and 8 are perspective views illustrating a side view type LED package 100 according to another exemplary embodiment of the present invention.

Referring to FIGS. 7 to 8, LED package 100 includes housing 101 and lead frame 130. Housing includes reflecting housing 110 and supporting housing 120. Supporting housing 120 is attached to a rear side of reflecting housing 110. Lead frame 130 on which an LED chip (not shown) will be mounted is interposed between reflecting housing 110 and supporting housing 120.

A cavity 112 is prepared in reflecting housing 110 by having an inner wall 111 formed in the inside of reflecting housing 110. Inner wall 111 is inclined at a prescribed angle with respect to a front and rear axis, so that cavity 112 may be narrow in width as going in the rear direction.

Reflecting housing 110 has an upper portion 113 and lower portion 114. A width W of upper portion 113 may be equal to that of lower portion 114 over the entire front surface of reflecting housing 110. Upper portion 113 and lower portion 114 may be symmetrical to each other with respect to a horizontal axis C.

Reflecting housing 110 may have a barrier wall 116 protruded from its front surface.

Barrier wall 116 is extended from inner wall 111 and prevents the overflow of a sealer (not shown) to be filled in cavity 112 to protect the LED chip (not shown).

Supporting housing 120 may be recessed such that a first width H and a first height V of supporting housing 120 are smaller than a second width H′ and a second height V′ of reflecting housing 110, respectively.

This leaves spaces S1 and S2 in supporting housing 120.

A part of lead frame 130 on which the LED chip (not shown) will be mounted is placed on supporting housing 120 and exposed externally through cavity 112, and an end of the lead frame 130 is extended in the rear direction through a groove 115 that has been prepared in left and right side of reflecting housing 110 or supporting housing 120.

The extended part of lead frame 130 is subsequently bent along bottom side, left and right side, and then front side, thereby ending up being located in spaces S1 and S2.

A part of the lead frame 130, located in space S1, may be perpendicularly with respect to horizontal axis C.

Accordingly, second width H′ of reflecting housing 110 is equal to the sum of first width H of supporting housing 120 and twice a third width L of a part of lead frame 130 extended in the left or right direction, and second height V′ of reflecting housing 110 is equal to the sum of first height V of supporting housing 120 and a third height L′ of a part of lead frame 130 extended in the front direction.

As a result, lead frame 130 may be completely covered by reflecting housing 110 as seen from the front side of LED package 100.

Therefore, reflecting housing 110 may be expanded as much as a space which has been occupied by the extended portion of lead frame 130, which in turn may increase the superficial area of cavity 112.

A consequence is the increase in the amount of light and radiating range of beams generated from LED chip (not shown).

As described above, an end of lead frame 130 conventionally protruding outside reflecting housing 110 may be concealed in spaces S1 and S2 formed in supporting housing 120 not to be seen from the front side, and this may increase a light emitting surface as compared to the prior art.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. A side view light emitting diode package comprising:
a housing including a reflecting housing having a cavity and a supporting housing attached to a rear portion of the reflecting housing, the supporting housing having a recessed space; and
a lead frame interposed between the reflecting housing and the supporting housing, and extended externally through the housing, and bent along the recessed space.

2. The side view light emitting diode package of claim 1, wherein
one of the reflecting housing and the supporting housing has a groove in its bottom portion, and
the lead frame is extended externally from the groove, and disposed at the bottom portion of the reflection housing.

3. The side view light emitting diode package of claim 2, wherein
the lead frame is extended under the bottom portion of the supporting housing and bent along the recessed space.

4. The side view light emitting diode package of claim 3, wherein
the lead frame is extended and bent to be shaped as a reversed “T” as seen from a rear side of the light emitting diode package.

5. The side view light emitting diode package of claim 1, wherein
one of the reflecting housing and the supporting housing has a groove in its side portion, and
the lead frame is extended from the groove, and disposed at a bottom portion of the supporting housing.

6. The side view light emitting diode package of claim 5, wherein
the lead frame is extended under a side portion of the supporting housing and is bent along the recessed space.

7. The side view light emitting diode package of claim 1, wherein
the lead frame is protruded at an outline of the reflecting housing.

8. The side view light emitting diode package of claim 1, wherein
the lead frame is covered by the reflecting housing as seen from a front side of the light emitting diode package.

9. The side view light emitting diode package of claim 1, wherein
the reflecting housing has an upper portion and a lower portion, and the upper portion has the same thickness as that of the lower portion.

10. The side view light emitting diode package of claim 9, wherein
the upper portion of the reflecting housing is symmetrical to the lower portion of the reflecting housing with respect to a middle line between the upper portion and the lower portion of the reflecting housing.

11. The side view light emitting diode package of claim 1, wherein
the reflecting housing has a barrier wall protruded from a front surface of the reflecting housing to surround the cavity.
